(19) United States
(12) Patent Application Publication
(10) Pub. No.: US 2024/0410745 A1
(43) Pub. Date: Dec. 12, 2024

(54) Vibration Measurement Device

(71) Applicant: Daifuku Co., Ltd., Osaka-shi (JP)

(72) Inventors: Daisuke Ogawa, Hinocho (JP); Kenshin Hashiguchi, Hinocho (JP); Daichi Tomida, Hinocho (JP)

(21) Appl. No.: 18/735,962

(22) Filed: Jun. 6, 2024

(30) Foreign Application Priority Data
Jun. 7, 2023 (JP) 2023-094119

(51) Int. Cl. G01H 17/00; B61K 9/00

(52) U.S. Cl. CPC G01H 17/00; B61K 9/00

(57) ABSTRACT

A vibration measurement device is mountable on a transport vehicle. The device includes a vibration measurer that measures vibration, a position information obtainer that obtains position information indicating a position of the transport vehicle, a state information obtainer that obtains vehicle state information indicating a state of the transport vehicle, a recorder that records a measurement result from the vibration measurer, the vehicle state information, and the position information in an associated manner, and an output unit that outputs information recorded in the recorder.

### CROSS-REFERENCE TO RELATED APPLICATION

This application claims priority to Japanese Patent Application No. 2023-094119 filed Jun. 7, 2023, the disclosure of which is hereby incorporated by reference in its entirety.

### BACKGROUND OF THE INVENTION

### Field of the Invention

The present invention relates to a vibration measurement device mountable on a transport vehicle.

### Description of Related Art

An example of such a vibration measurement device is described in Patent Literature 1 (Japanese Unexamined Patent Application Publication No. 2008-181245) below. In the background described hereafter, reference signs and names in parentheses are the reference signs and the names in Patent Literature 1.

Vibration measurement devices (vibration detectors 21) in Patent Literature 1 are mounted on transport vehicles (automated guided vehicles 10) that travel along a travel path (travel rail 2). Such a transport vehicle (10) also includes a traveling position detection sensor (22) for detecting its current traveling position. The transport vehicle (10) communicates, with a following transport vehicle (10), a traveling position at which a detected value of its vibration is greater than or equal to a predetermined value. Upon communication of the traveling position at which the detected value of vibration is greater than or equal to the predetermined value from the preceding transport vehicle (10), the transport vehicle (10) performs control for reducing its travel speed when traveling the position. The transport vehicle (10) also performs control for reducing its travel speed when its vibration detector (21) detects a value of vibration greater than or equal to the predetermined value.

As described in Patent Literature 1, with the vibration measurement devices (21) and the traveling position detection sensors (22) mounted on the transport vehicles (10), one transport vehicle (10) passing through a site with an unexpected situation, such as a damaged travel rail, can detect the abnormality, and thus can prevent greater damage from vibration.

However, with the vibration measurement device mounted on the transport vehicle, the state of the transport vehicle, such as acceleration or deceleration of the transport vehicle, may affect the transport vehicle to vibrate largely. Thus, large vibration measured in one transport vehicle may not have resulted from a defect in a travel path such as a travel rail.

The cause of the measured vibration is to be analyzed appropriately.

### SUMMARY OF THE INVENTION

In response to the above, a vibration measurement device is mountable on a transport vehicle. The device includes a vibration measurer that measures vibration, a position information obtainer that obtains position information indicating a position of the transport vehicle, a state information obtainer that obtains vehicle state information indicating a state of the transport vehicle, a recorder that records a measurement result from the vibration measurer, the vehicle state information, and the position information in an associated manner, and an output unit that outputs information recorded in the recorder.

This structure can obtain information indicating the vibration measured at positions on the travel path on which the transport vehicle has traveled and the state of the transport vehicle at the positions. A user receiving the output information can thus appropriately obtain information such as a position on the travel path of the transport vehicle at which vibration is larger and the state of the transport vehicle when vibration is larger. In other words, the vibration measurement device with this structure can output information for allowing appropriate analysis of the cause of measured vibration.

Further aspects and features of the vibration measurement device will be apparent from embodiments described below with reference to the drawings.

### BRIEF DESCRIPTION OF THE DRAWINGS

FIG. 1 is a plan view of an article transport facility in which a vibration measurement device measures vibration.

FIG. 2 is a side view of a transport vehicle including the vibration measurement device.

FIG. 3 is a schematic block diagram of the transport vehicle and the vibration measurement device.

FIG. 4 is a diagram describing the operation of guide wheels.

FIG. 5 is a diagram describing the operation of the guide wheels.

FIG. 6 is a diagram describing a detection area for an object detection sensor in the transport vehicle.

FIG. 7 is a diagram describing the detection area for the object detection sensor in the transport vehicle.

FIG. 8 is a schematic block diagram of a container and the vibration measurement device.

### DESCRIPTION OF THE INVENTION

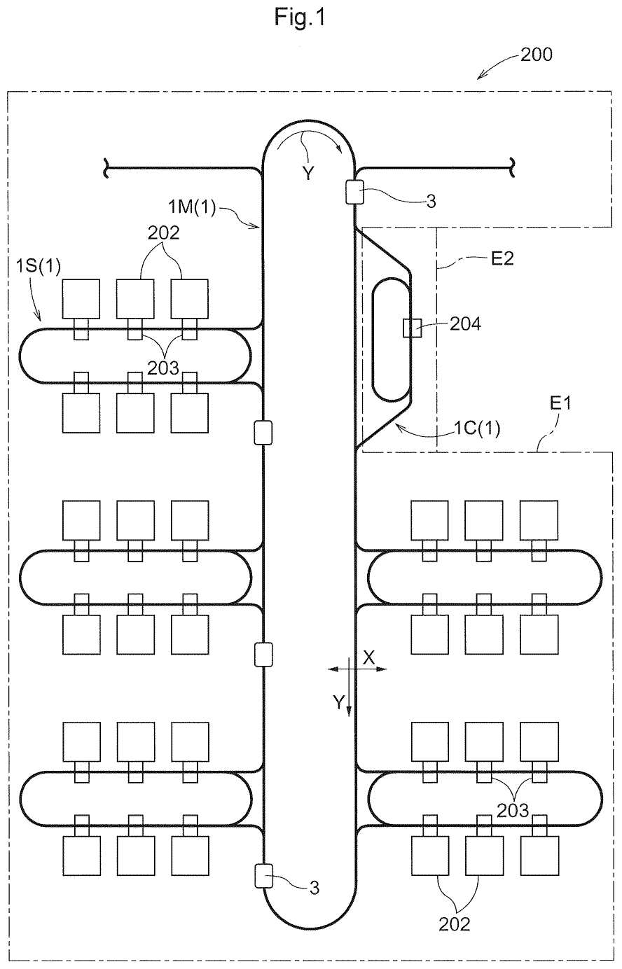

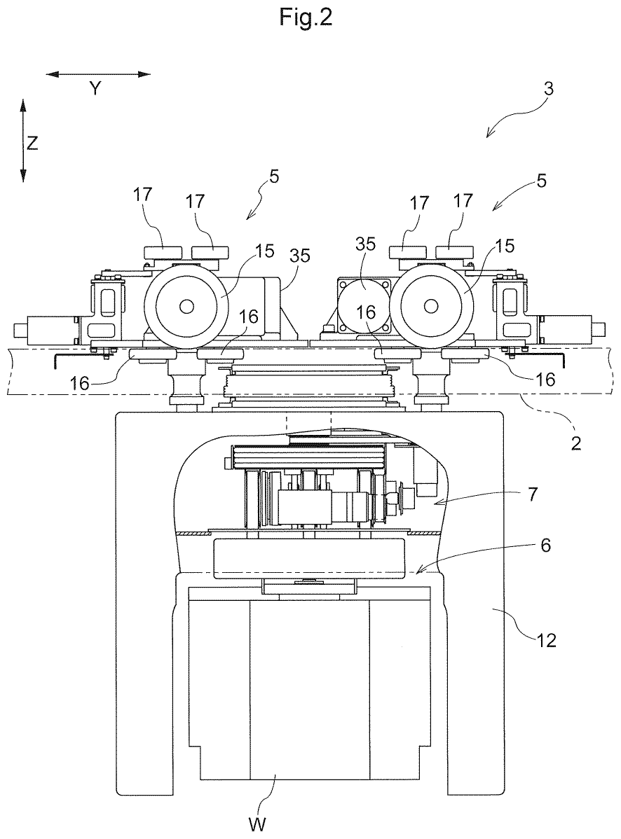

A vibration measurement device 20 according to an embodiment will now be described with reference to the drawings. In the example described in the present embodiment, the vibration measurement device 20 is mounted on a transport vehicle 3 for transporting an article, and measures vibration. FIG. 1 is a plan view of an article transport facility 200 in which the vibration measurement device 20 measures vibration. FIG. 2 is a side view of the transport vehicle 3 including the vibration measurement device 20.

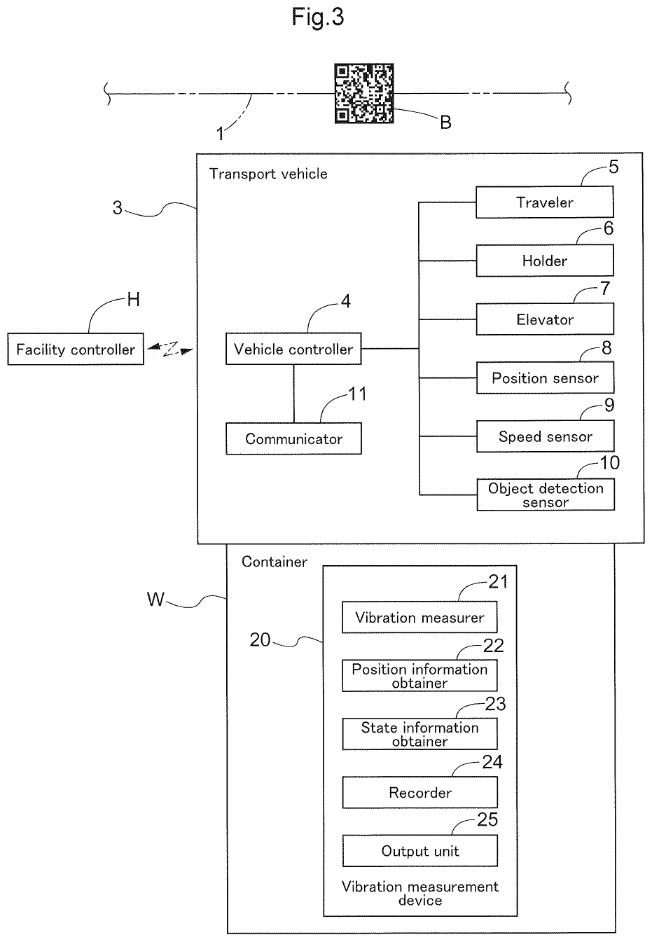

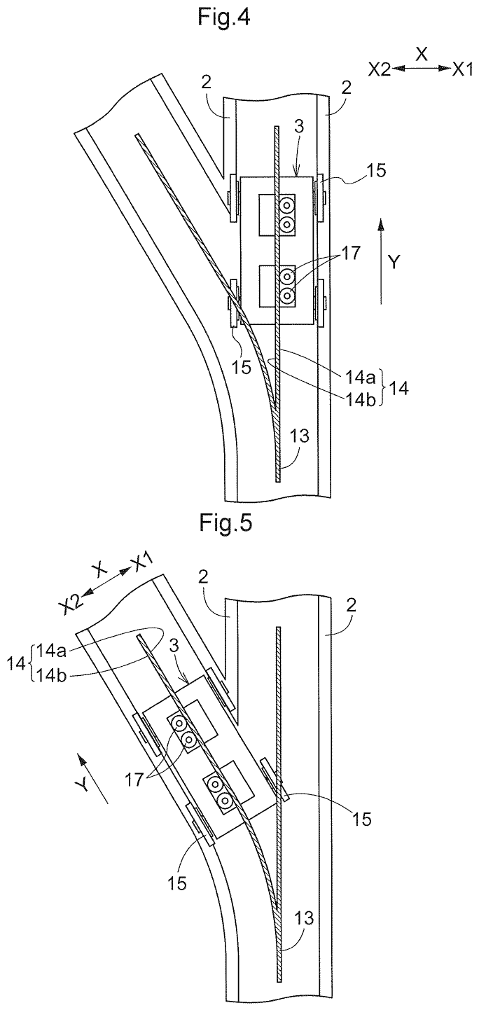

FIG. 3 is a schematic block diagram of the transport vehicle 3 and the vibration measurement device 20. FIGS. 4 and 5 are diagrams describing the operation of guide wheels 17 included in the transport vehicle 3. The direction along a travel path 1 is hereafter referred to as a travel direction Y, and the direction parallel to a horizontal plane and perpendicular to the travel direction Y is hereafter referred to as a width direction X. A vertical direction Z is a direction perpendicular to the travel direction Y and to the width direction X.

The article transport facility 200 includes travel rails 2 hung from the ceiling and installed along the travel path 1 and the transport vehicles 3 that are hung from the travel rails 2 and travel on the travel rails 2 along the travel path 1 to transport containers W. In other words, the transport vehicles 3 described in the present embodiment are ceiling-hung transport vehicles. The transport vehicles 3 transport, for example, front opening unified pods (FOUPs) containing articles, such as wafers being materials for semiconductor substrates, as the containers W.

As shown in FIG. 1, the travel path 1 includes, for example, an annular primary path 1M, multiple annular secondary paths 1S through multiple processing devices 202, and a maintenance path 1C included in a maintenance area E2 (described later). The travel path 1 is one-way. The transport vehicles 3 travel on the travel path 1 from upstream to downstream in the travel direction Y. The travel path 1 includes a transport area E1 and the maintenance area E2. The transport vehicles 3 travel in the transport area E1 when transporting the containers W and in the maintenance area E2 when undergoing maintenance. The maintenance area E2 includes, for example, a maintenance lifter 204 for lowering a transport vehicle 3 hung from the travel rails 2 toward the ground for maintenance. As shown in FIGS. 4 and 5, the transport vehicles 3 are guided with a pair of the travel rails 2.

The processing devices 202 are, for example, semiconductor processing devices for performing various processes such as an exposure process and an etching process. In this case, the FOUPs described above are transported as the containers W in the article transport facility 200. The containers W and the articles contained in the containers W may be other containers and articles. For example, the articles may be reticles used in the exposure process of a wafer in the manufacturing process of a semiconductor substrate, and the transport vehicles 3 may transfer reticle pods containing reticles as the containers W. Each processing device 202 also includes a mount 203.

As shown in FIG. 2, each transport vehicle 3 includes travelers 5 and a transport vehicle body 12. The travelers 5 travel along the travel path 1 while being guided by the travel rails 2 hung from the ceiling along the travel path 1. The transport vehicle body 12 below the travel rails 2 is hung from the travelers 5. The transport vehicle 3 also includes a holder 6 for hanging and holding the container W and an elevator 7 for lifting and lowering the holder 6. As shown in FIG. 2, the transport vehicle 3 travels with the holder 6 being lifted and transports the container W.

As shown in FIGS. 2, 4, and 5, each traveler 5 includes a pair of travel wheels 15 that are rotatably drivable by an electric travel actuator 35. The travel actuator 35 is, for example, a motor (travel motor). The travel wheels 15 roll on the upper surfaces of the travel rails 2 that serve as traveling surfaces. Although not shown in detail, the traveler 5 includes a pair of auxiliary wheels 16 that are freely rotatable about axes parallel to the vertical direction Z. The auxiliary wheels 16 are in contact with the inner surfaces of the travel rails 2 in the pair.

As shown in FIGS. 4 and 5, the travel path 1 includes a guide rail 13 extending in the travel direction Y of the transport vehicles 3 in its branching section. Although not shown, the travel path 1 also includes a similar guide rail 13 in its merging section. The guide rail 13 has a pair of guide surfaces 14 (a first guide surface 14a and a second guide surface 14b). The pair of guide surfaces 14 (the first guide surface 14a and the second guide surface 14b) face in the opposite directions in the width direction X, which is perpendicular to the travel direction Y, and extend in the travel direction Y. Each transport vehicle 3 includes the guide wheels 17 that are rotatable about vertical axes parallel to the vertical direction Z. The guide wheels 17 can change their positions to the right or to the left of the guide rail 13 located in the middle of the pair of left and right travel rails 2. The guide wheels 17 rotate while being in contact with the first guide surface 14a that is a right guide surface 14 of the guide rail 13 or with the second guide surface 14b that is a left guide surface 14.

As described below, each transport vehicle 3 includes a vehicle controller 4 that causes the travelers 5 to perform a switching operation of causing, in the branching section and in the merging section, the guide wheels 17 to be in contact with either the guide surfaces 14 in the pair.

In the example in FIG. 4, the transport vehicle 3 heading in the travel direction Y travels to a path on the right (or moves straight in this example) in the branching section. In this case, the vehicle controller 4 causes the guide wheels 17 to be on the first guide surface 14a of the guide rail 13 (on the right in the travel direction Y). The transport vehicle 3 thus travels with the guide wheels 17 in contact with the first guide surface 14a of the guide rail 13. As shown in FIG. 4, as the transport vehicle 3 moves straight on the path on the right (in a first width direction X1) in the branching section, one of the left and right travel rails 2 (the left travel rail 2 herein) ends, causing the travel wheels 15 and the auxiliary wheels 16 on the left to be derailed. The auxiliary wheels 16 are not shown in FIG. 4 for simplicity. However, the guide rail 13 receiving the load of the transport vehicle 3 through the guide wheels 17 supports and guides the transport vehicle 3. Thus, the transport vehicle 3 does not fall off the travel rail 2 and can travel straight in the branching section.

In the example in FIG. 5, the transport vehicle 3 heading in the travel direction Y travels to a path on the left (or moves sideways along the curved path in this example) in the branching section. In this case, the vehicle controller 4 causes the guide wheels 17 to be on the second guide surface 14b of the guide rail 13 (on the left in the travel direction Y). The transport vehicle 3 is thus guided with the guide wheels 17 in contact with the second guide surface 14b of the guide rail 13. As shown in FIG. 5, as the transport vehicle 3 moves sideways on the path on the left (in a second width direction X2) in the branching section, one of the left and right travel rails 2 (the right travel rail 2 herein) ends, causing the travel wheels 15 and the auxiliary wheels 16 on the right to be derailed. However, the guide rail 13 receiving the load of the transport vehicle 3 through the guide wheels 17 supports and guides the transport vehicle 3. Thus, the transport vehicle 3 does not fall off the travel rail 2 and can travel sideways in the branching section.

As shown in FIG. 3, the transport vehicle 3 includes a position sensor 8, a speed sensor 9, an object detection sensor 10, and a communicator 11, in addition to the components described above.

The vehicle controller 4 controls the operation of the transport vehicle 3. For example, the vehicle controller 4 can communicate information wirelessly with a facility controller H, which manages the entire article transport facility 200, through the communicator 11. The vehicle controller 4 causes the transport vehicle 3 to travel, transport the container W between different mounts 203, stop above a specified mount 203, and then lower and lift the holder 6 to transfer the container W through autonomous control in response to a transport command from the facility controller H.

The position sensor 8 detects the position of the transport vehicle 3. For example, as shown in FIG. 3, multiple position indicators B indicating positions on the travel path 1 are located along the travel path 1. The position indicators B can be, for example, one- or two-dimensional barcodes or markers with numbers or characters. The position sensor 8 can be a barcode reader, an image recognition device, or a character recognition device that recognizes numbers and characters. The position sensor 8 can derive the distance traveled by the transport vehicle 3 using, for example, a sensor for detecting the rotation angle of a wheel axle (not shown) of the travel wheels 15. The position sensor 8 can then detect the current position of the transport vehicle 3 on the travel path 1 based on the distance traveled by the transport vehicle 3 after detection of the position indicator B. The position information detected by the position sensor 8 is transmitted to the vehicle controller 4. In this manner, the transport vehicle 3 can detect its position on the travel path 1 using the multiple position indicators B. The transport vehicle 3 transmits the detected position information sequentially to the facility controller H, and the facility controller H can transmit a transport command generated based on the position information to the transport vehicle 3.

The speed sensor 9 detects the travel speed of the transport vehicle 3. The speed sensor 9 can be implemented by, for example, a sensor for detecting the rotation angle of the wheel axle (not shown) of the travel wheels 15. In this case, the speed sensor 9 derives the rotational speed of the wheel axle based on the rotation angle of the wheel axle (not shown) of the travel wheels 15, and then can derive the travel speed of the transport vehicle 3. The speed sensor 9 may transmit the derived travel speed to the vehicle controller 4. Alternatively, the speed sensor 9 may sequentially transmit the measured rotation angles of the wheel axle (not shown) of the travel wheels 15 to the vehicle controller 4, and the vehicle controller 4 may derive the travel speed of the transport vehicle 3 based on the value of the rotation angle.

The object detection sensor 10 detects an object that blocks a traveling transport vehicle 3. For example, multiple transport vehicles 3 travel on the travel path 1 at the same time. To avoid collisions between the transport vehicles 3, each transport vehicle 3 includes the object detection sensor 10 that detects an object in a predetermined area defined ahead in the travel direction Y.

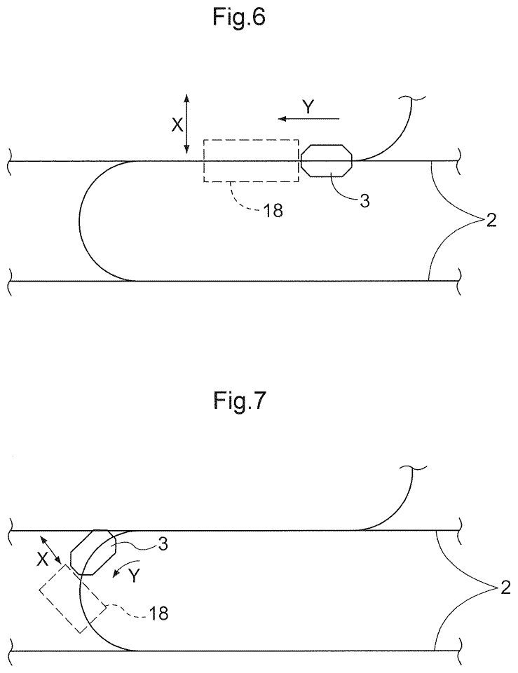

FIGS. 6 and 7 are diagrams describing a detection area 18 for the object detection sensor 10 in the transport vehicle 3. As shown in FIG. 6, for the transport vehicle 3 heading to a straight section in the travel direction Y, the detection area 18 defined ahead of the transport vehicle 3 in the travel direction Y has a shape longer in the travel direction Y than in the width direction X. As shown in FIG. 7, for the transport vehicle 3 heading to a curved section in the travel direction Y, the detection area 18 defined ahead of the transport vehicle 3 in the travel direction Y has a shape longer in the width direction X than in the travel direction Y based on the shape of the curved travel path 1.

The vibration measurement device 20 mounted on the transport vehicle 3 will now be described. As shown in FIG. 3, the vibration measurement device 20 includes a vibration measurer 21, a position information obtainer 22, a state information obtainer 23, a recorder 24, and an output unit 25. The vibration measurer 21 measures vibration. The position information obtainer 22 obtains position information indicating the position of the transport vehicle 3. The state information obtainer 23 obtains vehicle state information indicating the state of the transport vehicle 3. The recorder 24 records measurement results from the vibration measurer 21, the vehicle state information, and the position information in an associated manner. The output unit 25 outputs information recorded in the recorder 24. The vibration measurement device 20 has, for example, an information communication function, an information computation processing function, and an information storage function. As described later, the vibration measurement device 20 may use at least part of these functions to implement the functions of the vibration measurer 21, the position information obtainer 22, the state information obtainer 23, the recorder 24, and the output unit 25. The vibration measurement device 20 may be implemented by a single device having these functions or multiple devices having these functions.

The vibration measurer 21 can be implemented by a sensor that can measure the physical quantities of vibration, such as amplitude, frequency, and acceleration of the vibration. The vibration measurer 21 may measure vibration in three directions perpendicular to one another, such as the X-, Y-, and Z-directions. The vibration measurer 21 may measure vibration in one or two directions of the X-, Y-, and Z-directions. The vibration measurer 21 may obtain, in addition to the measurement results of vibration, time information about the time at which the measurement results are obtained.

The position information obtainer 22 obtains position information indicating the position of the transport vehicle 3. For example, the position information obtainer 22 uses the information communication function of the vibration measurement device 20 to obtain the position information about the transport vehicle 3 detected by the position sensor 8 in the transport vehicle 3. The position information obtainer 22 may obtain information about the time at which the position information is detected in addition to the position information.

The state information obtainer 23 obtains vehicle state information indicating the state of the transport vehicle 3. For example, the state information obtainer 23 uses the information communication function of the vibration measurement device 20 to obtain the vehicle state information measured by the transport vehicle 3. The state information obtainer 23 may obtain time information about the time at which the vehicle state information is obtained, together with the vehicle state information.

The vehicle state information includes at least one of the travel speed of the transport vehicle 3, the acceleration state of the transport vehicle 3, the operation state of an operation assembly included in the transport vehicle 3, or the detection state of the sensor (e.g., the object detection sensor 10) included in the transport vehicle 3.

The travel speed of the transport vehicle 3 is a value measured by the speed sensor 9 in the transport vehicle 3. The acceleration state (specifically, the acceleration indicating an increasing speed, a decreasing speed, or a constant speed) of the transport vehicle 3 is determined by computing changes in the travel speed measured by the speed sensor 9 in the transport vehicle 3. The vehicle controller 4 in the transport vehicle 3 may compute the acceleration state of the transport vehicle 3, and the state information obtainer 23 in the vibration measurement device 20 may obtain the computed acceleration state. Alternatively, the state information obtainer 23 in the vibration measurement device 20 may use the computation processing function of the vibration measurement device 20 to compute the acceleration state based on the obtained travel speed of the transport vehicle 3. For example, an accelerating or decelerating transport vehicle 3 vibrates relatively largely, and a transport vehicle 3 traveling at a constant speed vibrates relatively slightly.

The operation state of the operation assembly included in the transport vehicle 3 is information about the operation state of the operation assembly in the transport vehicle 3, such as the travelers 5, the holder 6, and the elevator 7. For example, the transport vehicle 3 includes the guide wheels 17 shown in FIGS. 4 and 5 as a part of each traveler 5. The operation of the guide wheels 17 is controlled by the vehicle controller 4. The state information obtainer 23 can obtain, from the vehicle controller 4 in the transport vehicle 3, information indicating that the guide wheels 17 are on the right or on the left in the travel direction Y. The operation state is not limited to the state of the guide wheels 17 (in other words, the travelers 5). For example, the operation state may include the operation state of the elevator 7 and the operation state of the holder 6. When the guide wheels 17 in the travelers 5 operate (specifically, when the guide wheels 17 change their positions between the left and the right), for example, the transport vehicle 3 may vibrate relatively largely.

The detection state of the object detection sensor 10 included in the transport vehicle 3 is, for example, information about the shape of the detection area 18 for the object detection sensor 10 shown in FIGS. 6 and 7 or information about whether an object is detected. The state of the detection area 18 for the object detection sensor 10 in the transport vehicle 3 is controlled by the vehicle controller 4. Information about whether the object detection sensor 10 has detected an object is transmitted to the vehicle controller 4. The state information obtainer 23 can obtain information about the detection state of the object detection sensor 10 in the transport vehicle 3 from the vehicle controller 4 in the transport vehicle 3. When the object detection sensor 10 detects an object, for example, the transport vehicle 3 decelerates. This may cause the transport vehicle 3 to vibrate relatively largely.

As described above, the state information obtainer 23 can obtain, as the vehicle state information, information indicating behavior of the transport vehicle 3 that possibly affects vibration measured by the vibration measurer 21. Thus, the user referring to the vehicle state information can easily perform analysis to determine whether the vibration is greatly affected by the state of the transport vehicle 3.

The recorder 24 records the measurement results (vibration information) from the vibration measurer 21, the vehicle state information, and the position information in an associated manner. The recorder 24 can be implemented using the information storage function of the vibration measurement device 20. When the measurement results from the vibration measurer 21, the vehicle state information, and the position information are each associated with the time information as described above, for example, the recorder 24 can record the measurement results from the vibration measurer 21, the vehicle state information, and the position information obtained at the same time or within a predetermined time range in an associated manner. When items in the above information are not associated with the time information, the recorder 24 may record the measurement results from the vibration measurer 21, the vehicle state information, and the position information recorded at the same time or within the predetermined time range as one dataset in an associated manner.

The vibration information may be information about the physical quantities of vibration, such as the amplitude, frequency, and acceleration of the vibration measured by the vibration measurer 21, or values computed from such physical quantities. For example, the vibration information may include an effective value (root-mean-square or RMS) computed using a vibration waveform.

In this manner, the recorder 24 can record transport vehicle travel data that is data including, in an associated manner, at least the position information indicating the position of the transport vehicle 3 and the vibration information indicating the vibration measured in the transport vehicle 3 or transport vehicle travel data that is data including, in an associated manner, at least the position information indicating the position of the transport vehicle 3, the vibration information indicating the vibration measured in the transport vehicle 3, and the vehicle state information indicating the state of the transport vehicle 3. The position information, the vibration information, and the vehicle state information included in the transport vehicle travel data may be associated with the time information. The recorder 24 can record, as path map data, information about the positions through which the transport vehicle 3 has traveled. The path map data includes map data of the travel path 1 on which the transport vehicle 3 has traveled. The information about the positions through which the transport vehicle 3 has traveled may be associated with the time information.

The output unit 25 outputs information recorded in the recorder 24. For example, the output unit 25 uses the information communication function of the vibration measurement device 20 to output information recorded in the recorder 24 to another device that can communicate with the vibration measurement device 20. In addition to outputting information by transmitting the information to other devices, the output unit 25 may output information, for example, to a display device 41 for displaying, to paper for printing, or to a portable storage.

As described above, the vibration measurement device 20 according to the present embodiment can obtain information indicating vibration measured at positions on the travel path 1 on which the transport vehicle 3 has traveled and the state of the transport vehicle 3 at the positions.

Thus, the user receiving the output information can appropriately obtain information such as a position on the travel path 1 of the transport vehicle 3 at which vibration is larger and the state of the transport vehicle 3 when vibration is larger. In other words, the vibration measurement device 20 according to the present embodiment can output information for allowing appropriate analysis of the cause of the measured vibration.

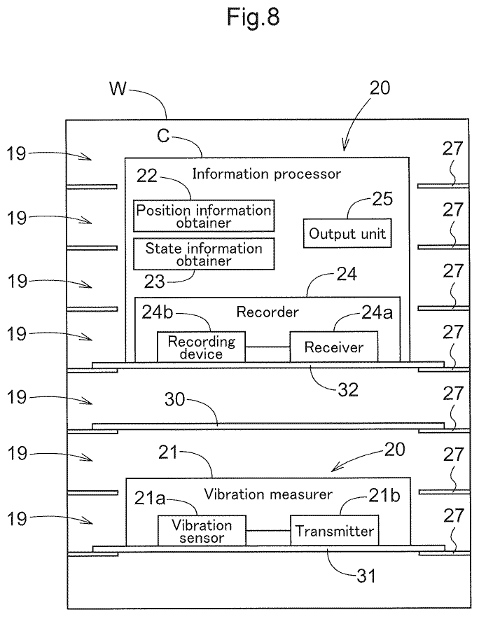

An example vibration measurement device 20 mounted on a container W will now be described. FIG. 8 is a schematic block diagram of the container W and the vibration measurement device 20. The vibration measurement device 20 is accommodated in the container W transported by the transport vehicle 3. The vibration measurement device 20 measures vibration in the transport vehicle 3 transporting the container W (in other words, in the traveling transport vehicle 3). More specifically, the vibration measurer 21 in the vibration measurement device 20 can measure vibration substantially the same as the vibration transmitted to an article when the transport vehicle 3 travels with the container W containing the article.

As illustrated, the container W is a box with a rectangular or substantially rectangular vertical section.

One of the side surfaces of the container W includes a door (not shown) that opens and closes. With the door open, an article can be placed into and removed from the internal space of the container W. A plate member 30 as an article contained in the container W shown in FIG. 8 is, for example, an actual wafer or a member similar to a wafer. As shown in FIG. 8, the transport vehicle 3 may travel with the container W accommodating the vibration measurement device 20 alone inside or with the container W accommodating the vibration measurement device 20 and the plate member 30.

The container W has multiple slots 19 that can receive, for example, the plate member 30 as an article to be transported by the transport vehicle 3 with the container W containing the article. More specifically, multiple partitions 27 are arranged on inner surfaces of the container W in the vertical direction Z. The spaces between the partitions 27 are the slots 19.

The vibration measurement device 20 shown in FIG. 8 can be installed inside the container W without changing the internal structure of the container W. More specifically, the vibration measurement device 20 includes two devices with functions of the position information obtainer 22, the state information obtainer 23, the recorder 24, and the output unit 25 in a distributed manner. A first device includes the vibration measurer 21, and a second device includes an information processor C. The information processor C can be implemented by, for example, a portable computer device or a tablet terminal that has, for example, an information communication function, an information storage function, and an information computation function.

The vibration measurement device 20 includes a first support 31 and a second support 32 placed in different slots 19. The vibration measurer 21 includes a vibration sensor 21a and a transmitter 21b that transmits the measurement results from the vibration sensor 21a, and is supported by the first support 31. For example, the vibration sensor 21a can be implemented by the acceleration sensor described above.

The second support 32 supports the information processor C. The information processor C includes the position information obtainer 22, the state information obtainer 23, the recorder 24, and the output unit 25. The recorder 24 includes a receiver 24a that receives the measurement results from the transmitter 21b and a recording device 24b such as a flash memory that records the measurement results received by the receiver 24a, and is supported by the second support 32. The transmitter 21b may communicate with the receiver 24a in a wired or wireless manner.

The communication between the transmitter 21b in the vibration measurer 21 supported on the first support 31 and the receiver 24a in the recorder 24 supported on the second support 32 is compliant with various communication standards such as the Bluetooth (registered trademark) standard. The measurement results from the vibration sensor 21a are sequentially recorded in the recording device 24b.

In the example shown in FIG. 8, the first support 31 and the second support 32 are placed in different slots 19. For the functions of the vibration measurer 21, the position information obtainer 22, the state information obtainer 23, the recorder 24, and the output unit 25 included in the vibration measurement device 20, components functioning as the vibration measurer 21 are mounted on the first support 31, and components functioning as the position information obtainer 22, the state information obtainer 23, the recorder 24, and the output unit 25 are mounted on the second support 32. This structure facilitates installation of the vibration measurer 21, the position information obtainer 22, the state information obtainer 23, the recorder 24, and the output unit 25 included in the vibration measurement device 20 inside the container W.

The first support 31 and the second support 32 can be placed in any slots 19 as appropriate. For example, the first support 31 supporting the vibration measurer 21 may be placed in a slot 19 in which vibration may be largest.

As described above, the multiple slots 19 in the container W may receive the plate member 30 as an article to be transported or the first support 31 supporting the vibration sensor 21a included in the vibration measurer 21. In other words, the vibration sensor 21a and the plate member 30 as an article to be transported can be in the same environment inside the container W. Thus, when the transport vehicle 3 transports the container W with the first support 31 supporting the vibration sensor 21a placed in the slot 19, the vibration measurer 21 can measure vibration substantially the same as the vibration on the plate member 30 as an article to be transported. The vibration measurement device 20 can also measure vibration on any transport vehicles 3 without preparing a special transport vehicle 3 for vibration measurement. In the present embodiment, the first support 31 supporting the vibration sensor 21a and the second support 32 supporting the receiver 24a and the recording device 24b are separate members placed in different slots 19. Thus, the vibration sensor 21a can measure vibration while being affected by a lesser degree by the receiver 24a and the recording device 24b. This can increase the accuracy of vibration measurement.

A vibration measurement device 20 according to other embodiments will now be described.
(1) In the above embodiment, the transport vehicles 3 are ceiling-hung transport vehicles. In some embodiments, the transport vehicles 3 may be automatic guided vehicles (AGVs), sorting transfer vehicles (STVs), stacker cranes, or autonomous mobile robots (AMRs).
(2) In the above embodiment, the position sensor 8 detects the position of the transport vehicle 3 based on the position indicator B indicating a position on the travel path 1. The position sensor 8 may detect the position of the transport vehicle 3 with another method. For example, the position sensor 8 may receive signals from global navigation satellite system (GNSS) satellites included in the GNSS and detect the position of the transport vehicle 3.
(3) In the above embodiment, the vehicle state information may include different items as appropriate. For example, the vehicle state information may include information about the detection state of various sensors included in the transport vehicles 3. Examples of the various sensors in the transport vehicles 3 include a sensor that detects the operation state of the holder 6 for holding the container W and a sensor that detects the operation state of the elevator 7 for lifting and lowering the holder 6.
(4) In the above embodiment, the transport vehicle 3 travels with the container W containing the plate member 30 being, for example, an actual wafer or a substrate similar to a wafer. The container W can contain any number of plate members 30 as appropriate. For example, the container W may contain no plate member 30. The number of plate members 30 may be adjusted to allow the container W to weigh close to a container W containing wafers as articles to be transported by the transport vehicle 3.
(5) The structure described in each of the above embodiments may be combined with any other structures described in the other embodiments unless any contradiction arises. For other structures as well, the embodiments described herein are merely illustrative in all respects and may be modified variously as appropriate without departing from the spirit and scope of the disclosure.

In one embodiment, a vibration measurement device is mountable on a transport vehicle. The device includes a vibration measurer that measures vibration, a position information obtainer that obtains position information indicating a position of the transport vehicle, a state information obtainer that obtains vehicle state information indicating a state of the transport vehicle, a recorder that records a measurement result from the vibration measurer, the vehicle state information, and the position information in an associated manner, and an output unit that outputs information recorded in the recorder.

This structure can obtain information indicating the vibration measured at positions on the travel path on which the transport vehicle has traveled and the state of the transport vehicle at the positions. The user receiving the output information can thus appropriately obtain information such as a position on the travel path of the transport vehicle at which vibration is larger and the state of the transport vehicle when vibration is larger. In other words, the vibration measurement device with this structure can output information for allowing appropriate analysis of the cause of measured vibration.

In one embodiment, the vehicle state information includes at least one of a travel speed of the transport vehicle, an acceleration state of the transport vehicle, an operation state of a traveler included in the transport vehicle, or a detection state of a sensor included in the transport vehicle.

This structure can obtain, as the vehicle state information, information indicating the behavior of the transport vehicle that possibly affects vibration measured by the vibration measurer. Thus, the user referring to the vehicle state information can easily perform analysis to determine whether the vibration is greatly affected by the state of the transport vehicle.

In one embodiment, the vibration measurer is accommodated in a container transported by the transport vehicle.

In this structure, the vibration measurer can measure vibration inside the container being transported. More specifically, the vibration measurer can measure vibration substantially the same as the vibration transmitted to an article when the transport vehicle travels with the container containing the article.

In one embodiment, the container has a plurality of slots to receive a plate member being an article to be transported in the container by the transport vehicle. The vibration measurement device includes a first support and a second support placed in different slots of the plurality of slots. The vibration measurer includes a vibration sensor and a transmitter that transmits a measurement result from the vibration sensor, and is supported by the first support. The recorder includes a receiver that receives the measurement result from the transmitter and a storage that stores the measurement result received by the receiver, and is supported by the second support.

In this structure, the vibration measurer and the recorder can be easily installed in the container by placing the first support and the second support in the slots. In this structure, the multiple slots in the container may receive the plate member as an article to be transported or the first support supporting the vibration sensor included in the vibration measurer. In other words, the vibration sensor and the plate member as an article to be transported can be in the same environment inside the container. Thus, when the transport vehicle transports the container with the first support supporting the vibration sensor placed in the slot, the vibration measurer can measure vibration substantially the same as the vibration on the plate member as an article to be transported. The vibration measurement device can also measure vibration on any transport vehicles without preparing a special transport vehicle for vibration measurement. In this structure, the first support supporting the vibration sensor and the second support supporting the receiver and the storage are separate members placed in different slots. Thus, the vibration sensor can measure vibration while being affected by a lesser degree by the receiver and the storage. This can increase the accuracy of vibration measurement.

The vibration measurement device according to one or more embodiments of the disclosure may produce at least one of the effects described above.

### INDUSTRIAL APPLICABILITY

The technique according to one or more embodiments of the disclosure can be used in a vibration measurement device that outputs information for allowing appropriate analysis of the cause of measured vibration.

What is claimed is:

1. A vibration measurement device mountable on a transport vehicle, the device comprising:
a vibration measurer configured to measure vibration;
a position information obtainer configured to obtain position information indicating a position of the transport vehicle;
a state information obtainer configured to obtain vehicle state information indicating a state of the transport vehicle;
a recorder configured to record a measurement result from the vibration measurer, the vehicle state information, and the position information in an associated manner; and
an output unit configured to output information recorded in the recorder.

2. The vibration measurement device according to claim 1, wherein:
the vehicle state information comprises at least one of a travel speed of the transport vehicle, an acceleration state of the transport vehicle, an operation state of a traveler in the transport vehicle, and a detection state of a sensor in the transport vehicle.

3. The vibration measurement device according to claim 1, wherein:
the vibration measurer is accommodated in a container transported by the transport vehicle.

4. The vibration measurement device according to claim 3, wherein:
the container has a plurality of slots to receive a plate member that is an article to be transported in the container by the transport vehicle,
the vibration measurement device comprises a first support and a second support placed in different slots of the plurality of slots,
the vibration measurer comprises a vibration sensor and a transmitter configured to transmit the measurement result from the vibration sensor and is supported by the first support, and
the recorder comprises a receiver configured to receive the measurement result from the transmitter and a storage configured to store the measurement result received by the receiver and is supported by the second support.
